(19) United States
(12) Patent Application Publication
(10) Pub. No.: US 2025/0105732 A1
(43) Pub. Date: Mar. 27, 2025

(54) CROSS-REGULATION OF POWER CONVERTERS

(71) Applicants: Keng Chen, Acton, MA (US); Arvind Raghavan, Lexington, MA (US); Tamir Salus, Zichron Yaakov (IL); Christopher Schaef, Hillsboro, OR (US); Huanhuan Zhang, Ashland, MA (US); Sivaraman Masilamani, Northborough, MA (US)

(72) Inventors: Keng Chen, Acton, MA (US); Arvind Raghavan, Lexington, MA (US); Tamir Salus, Zichron Yaakov (IL); Christopher Schaef, Hillsboro, OR (US); Huanhuan Zhang, Ashland, MA (US); Sivaraman Masilamani, Northborough, MA (US)

(21) Appl. No.: 18/372,939

(22) Filed: Sep. 26, 2023

(51) Int. Cl. H02M 3/06; H03K 5/26; H03M 1/66

(52) U.S. Cl. CPC H02M 3/06; H03K 5/26; H03M 1/66

(57) ABSTRACT

An apparatus includes a power converter with an input terminal and an output terminal. The apparatus further includes a first comparator. A first input of the first comparator is coupled to the output terminal of the power converter. The apparatus further includes a reference clock generator. An output of the reference clock generator is coupled to a second input of the first comparator. An input of the reference clock generator is coupled to a frequency comparator.

### BACKGROUND

When two or more switched capacitor power converters are regulated in parallel to provide energy to a particular load, the non-idealities can create a significant imbalance between those converters. Those non-idealities, including voltage mismatch on the ground routing/plane, residue input-referred offset voltage associated with the feedback sensing circuit, element placing mismatch, etc., can lead some of the switched capacitor power converters to deliver their maximum output power. In contrast, other converters may only deliver minimum output power. As a result, a sizeable transient output voltage droop occurs, which leads to low system efficiency.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 illustrates a graph of imbalanced ground triggering large transient output voltage (Vout) droop, in accordance with some embodiments;

FIG. 2 illustrates a graph of imbalanced ground voltage leading one of a group of continuous capacitive voltage regulators (C2VRs) (or power converters) to operate at maximum switching frequency while the other converter rarely fires pulses, in accordance with some embodiments;

FIG. 3 illustrates a graph of efficiency difference for two power converters operated in an unbalanced condition and a balanced condition, in accordance with some embodiments;

FIG. 4 is a diagram of a cross-regulation system using C2VRs, in accordance with some embodiments;

FIG. 5 is a diagram of a cross-regulation system using C2VRs, in accordance with some embodiments;

FIG. 6 is a diagram of the cross-regulation system implementation of FIG. 5 on a circuit-level testbench, in accordance with some embodiments;

FIG. 7 illustrates a graph of simulation results for the cross-regulation system implementation of FIG. 5, in accordance with some embodiments;

FIG. 8 illustrates a graph of simulation results for the cross-regulation system implementation of FIG. 5, in accordance with some embodiments;

FIG. 9 illustrates a graph of simulation results for the cross-regulation system implementation of FIG. 5, in accordance with some embodiments;

FIG. 10 is a diagram of a cross-regulation system using C2VRs on a circuit-level testbench, in accordance with some embodiments;

FIG. 11 is a diagram of an analog frequency-voltage converter followed by a voltage-to-current analog converter for averaging frequency over different converters, in accordance with some embodiments;

FIG. 12 is a diagram of a cross-regulation system using C2VRs, in accordance with some embodiments;

FIG. 13 is a flow diagram of an example method for generating an input clock signal for a power converter, in accordance with some embodiments; and

FIG. 14 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the multiple aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the functions (e.g., operations or methods disclosed herein) as well as multiple processors individually configured to carry out some or all of the operations (which may overlap) such that the combination of processors carry out all of the operations.

The regulation loop of high-speed switched capacitor power converters can be based on frequency modulation. Currently, there are limited solutions to balance these regulators, which do not have a fixed regulation frequency. For a system using buck converters, the current information is communicated between different regulators, and the current mismatch is to fine-tune the reference voltage of each regulator. Such previous solutions based on a system using fixed-frequency buck regulators need to access the current information of each regulator. For a buck regulator, it is easier to measure the current passing through the inductor. However, for a switched capacitor power converter using frequency modulation, it is challenging to measure its output current.

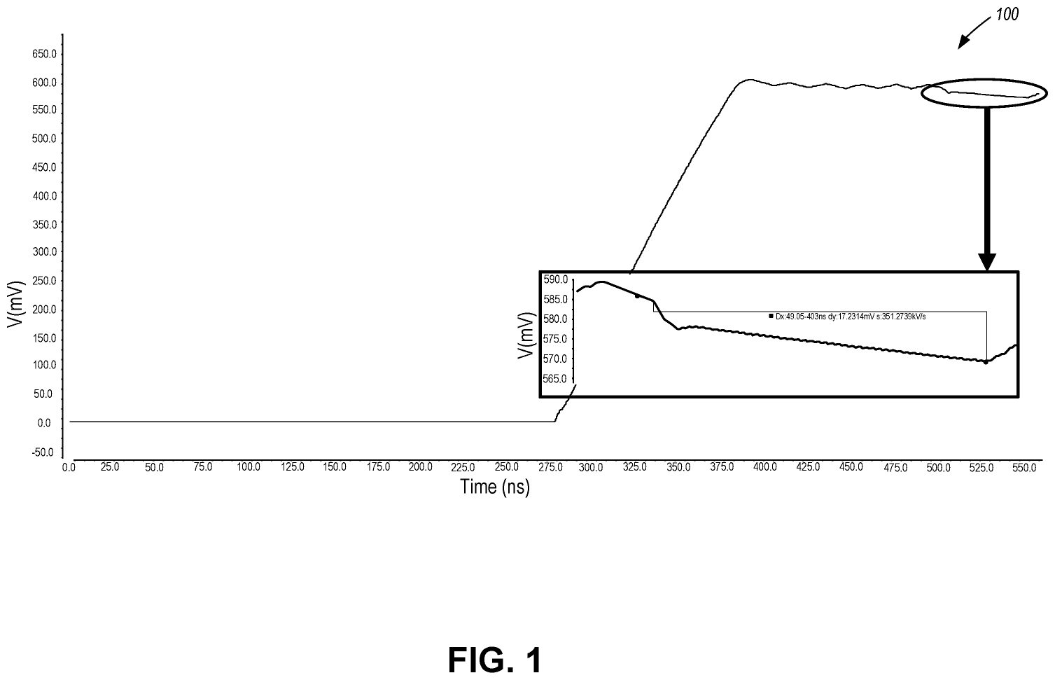

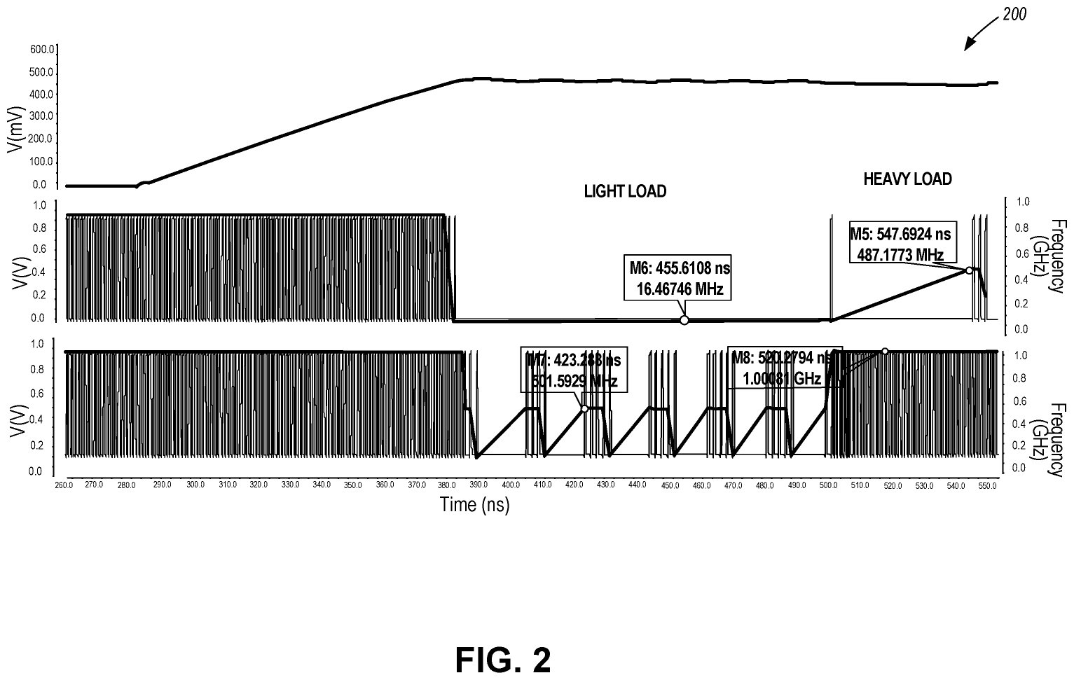

The disclosed cross-regulation balance techniques can be used to reduce transient output voltage droop and increase system efficiency in voltage supply systems using two or more switched capacitor power converters regulated in parallel to provide energy to a particular load. Example imbalances that can be prevented with the disclosed techniques are illustrated in FIG. 1 and FIG. 2.

FIG. 1 illustrates graph 100 of imbalanced ground triggering large transient output voltage (Vout) droop, in accordance with some embodiments.

FIG. 2 illustrates graph 200 of imbalanced ground voltage, leading one of a group of continuous capacitive voltage regulators (C2VRs) (or power converters) to operate at maximum switching frequency while the other converter rarely fires pulses, in accordance with some embodiments.

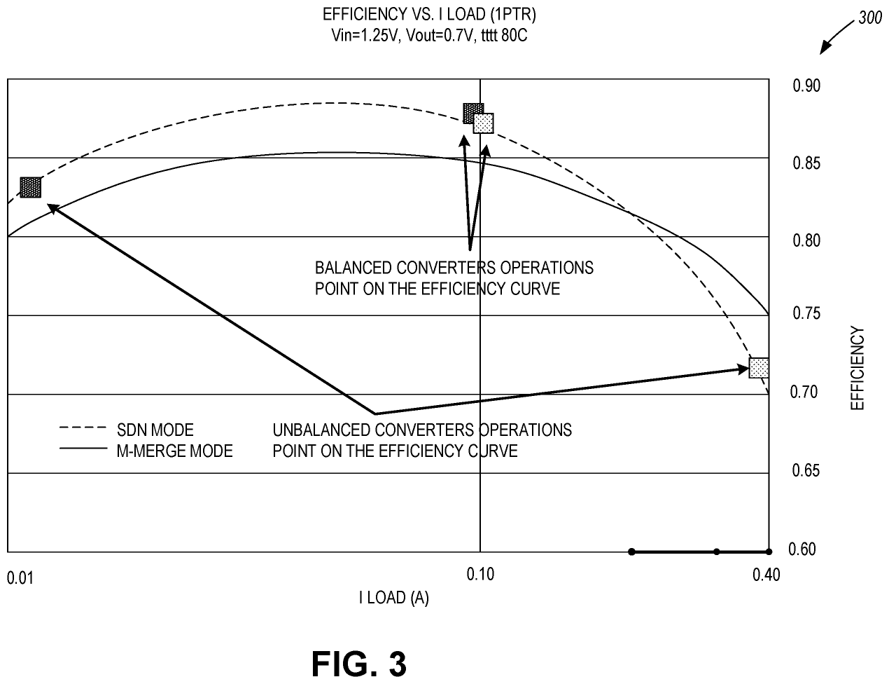

FIG. 3 illustrates graph 300 of the efficiency difference for two power converters operated in an unbalanced condition and a balanced condition, in accordance with some embodiments. More specifically, FIG. 3 presents the system's efficiency difference when there are two converters operated with unbalanced load distribution and balanced load distribution. When the load distribution is unbalanced, one of the converters is heavily loaded and operated in a low-efficiency region, while the other converter has a much lighter load. As a result, the efficiency of the light load converter is not as good as it is operated in the “sweet spot.”

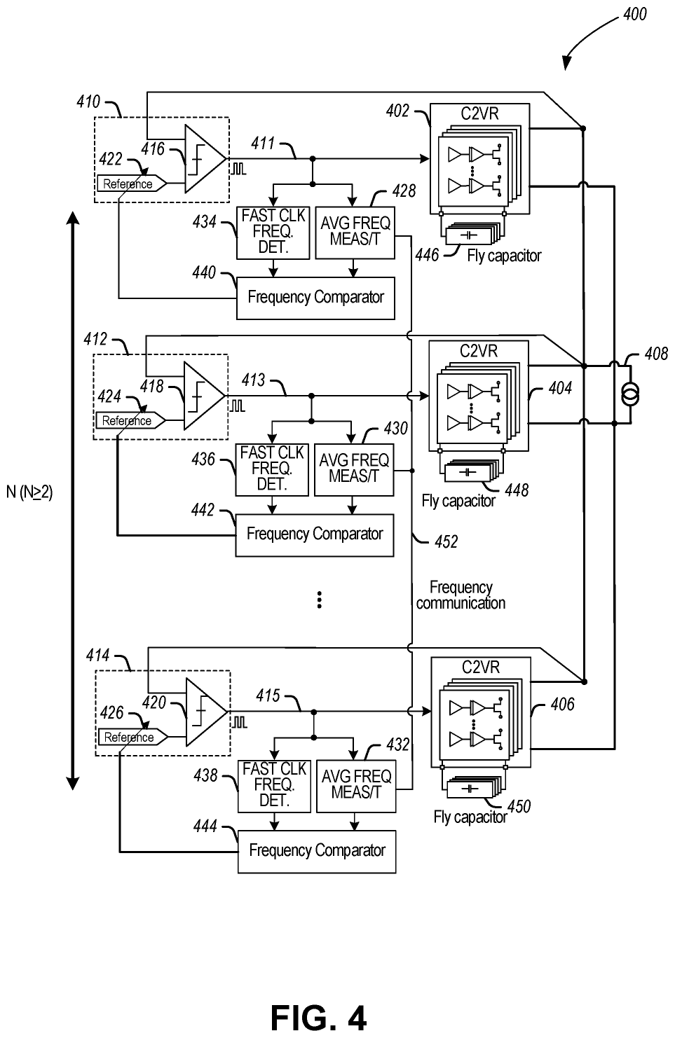

FIG. 4 is a diagram of a cross-regulation system 400 using C2VRs, in accordance with some embodiments. Referring to FIG. 4, the cross-regulation system 400 includes power converters 402, 404, . . . , 406 (e.g., C2VRs) using corresponding capacitor banks 446, 448, . . . , 450, and all coupled to load 408.

The power converter 402 generates output voltage using an input clock signal 411 generated by the clock generation circuit 410. The clock generation circuit 410 includes a comparator 416 and reference clock generator 422. Comparator 416 receives as a first input the output clock frequency associated with the output voltage signal generated by power converter 402. Comparator 416 also receives as a second input a reference clock signal generated by the reference clock generator 422.

The clock generation circuit is coupled to a fast clock frequency detection (FCFD) circuit 434 and a frequency measurement circuit 428. The frequency measurement (FM) circuit 428 comprises suitable circuitry, logic, interfaces, and/or code and is configured to generate an average clock signal based on the input clock signal 411 measured during a first pre-configured interval. The FCFD circuit 434 comprises suitable circuitry, logic, interfaces, and/or code and is configured to detect a clock frequency above a threshold during a second pre-configured interval. In some aspects, the first pre-configured interval is larger than the second pre-configured interval.

The frequency comparator 440 comprises suitable circuitry, logic, interfaces, and/or code and is configured to generate a clock comparison signal based on the detected clock frequency generated by the FCFD circuit 434 and the average clock signal generated by the FM circuit 428. The clock comparison signal generated by the frequency comparator 440 is communicated as input to the reference clock generator 422 and is used for generating the reference clock signal communicated as input to comparator 416.

The power converter 404 generates output voltage using an input clock signal 413 generated by the clock generation circuit 412. The clock generation circuit 412 includes a comparator 418 and reference clock generator 424. Comparator 418 receives as a first input the output clock frequency associated with the output voltage signal generated by power converter 404. Comparator 418 also receives as a second input a reference clock signal generated by the reference clock generator 424.

The clock generation circuit is coupled to an FCFD circuit 436 and an FM circuit 430. The FM circuit 430 comprises suitable circuitry, logic, interfaces, and/or code and is configured to generate an average clock signal based on the input clock signal 413 measured during a first pre-configured interval. The FCFD circuit 436 comprises suitable circuitry, logic, interfaces, and/or code and is configured to detect a clock frequency above a threshold during a second pre-configured interval. In some aspects, the first pre-configured interval is larger than the second pre-configured interval.

The frequency comparator 442 comprises suitable circuitry, logic, interfaces, and/or code and is configured to generate a clock comparison signal based on the detected clock frequency generated by the FCFD circuit 436 and the average clock signal generated by the FM circuit 430. The clock comparison signal generated by the frequency comparator 442 is communicated as input to the reference clock generator 424 and is used for generating the reference clock signal communicated as input to comparator 418.

The power converter 406 generates output voltage using an input clock signal 415 generated by the clock generation circuit 414. The clock generation circuit 414 includes a comparator 420 and reference clock generator 426. Comparator 420 receives as a first input the output clock frequency associated with the output voltage signal generated by power converter 406. Comparator 420 also receives as a second input a reference clock signal generated by the reference clock generator 426.

The clock generation circuit 414 is coupled to an FCFD circuit 438 and an FM circuit 432. The FM circuit 432 comprises suitable circuitry, logic, interfaces, and/or code and is configured to generate an average clock signal based on the input clock signal 415 measured during a first pre-configured interval. The FCFD circuit 438 comprises suitable circuitry, logic, interfaces, and/or code and is configured to detect a clock frequency above a threshold during a second pre-configured interval. In some aspects, the first pre-configured interval is larger than the second pre-configured interval.

The frequency comparator 444 comprises suitable circuitry, logic, interfaces, and/or code and is configured to generate a clock comparison signal based on the detected clock frequency generated by the FCFD circuit 438 and the average clock signal generated by the FM circuit 432. The clock comparison signal generated by the frequency comparator 444 is communicated as input to the reference clock generator 426 and is used for generating the reference clock signal communicated as input to comparator 420.

In some embodiments, a shared communication bus 452 is configured between FM circuits 428, 430, . . . , 432. The common communication bus can be used for communicating average clock signals or clock comparison signals generated by the corresponding FM circuits or frequency comparators. The average clock signals or clock comparison signals communicated via the common communication bus 452 can be used by a frequency comparator to adjust further its clock comparison signal that is communicated to the corresponding reference clock generator.

In some aspects, the shared communication bus 452 is used for communicating each switched capacitor power converter's fast comparator output clock (e.g., the output of each FCFD circuit) to every other converter for steady-state frequency adjustment. The average clock information can be achieved through at least one of the following techniques:
(a) Digital frequency measurement (measure the pulse counter over a period).
(b) Direct clock feed through (propagation of a reference clock to other converters).
(c) Frequency. The analog converter and then propagation of the analog information (voltage/current).

In some aspects, the reference voltage adjustment is based on the steady-state frequency adjustment signal and, for each converter, on a fast frequency detection path. This path can be used for comparing the instantaneous frequency spur over a running average frequency. The short cumulative error can trigger an adjustment in the reference voltage to handle transient conditions.

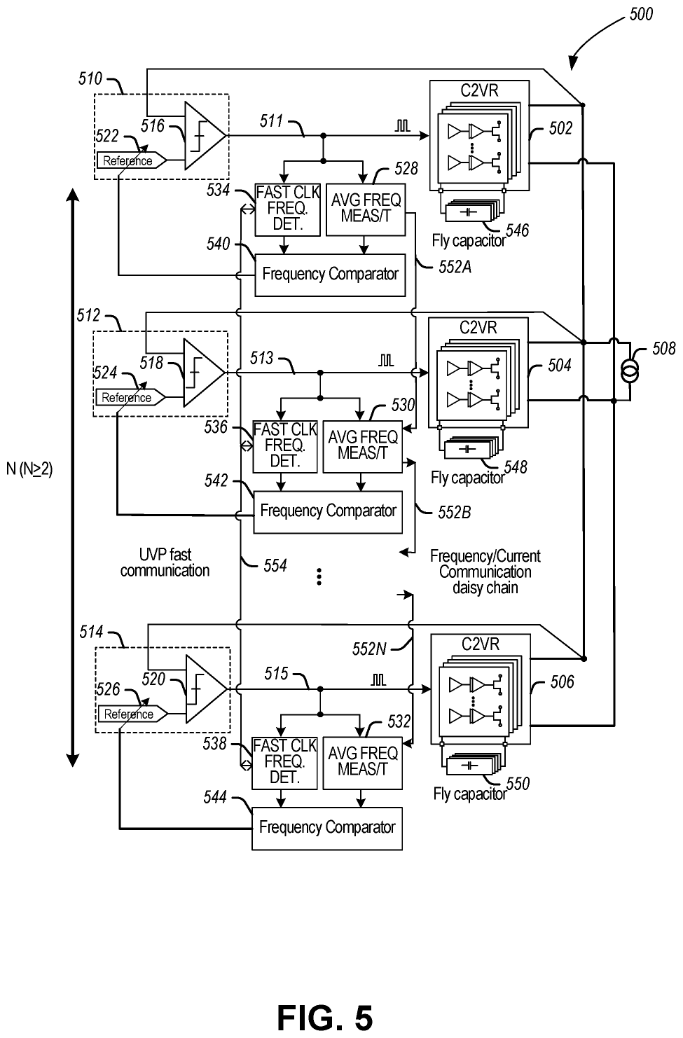

FIG. 5 is a diagram of a cross-regulation system using C2VRs, in accordance with some embodiments. Referring to FIG. 5, the cross-regulation system 500 includes power converters 502, 504, . . . , 506 (e.g., C2VRs) using corresponding capacitor banks 546, 548, . . . , 550, and all coupled to load 508.

The power converter 502 generates output voltage using an input clock signal 511 generated by the clock generation circuit 510. The clock generation circuit 510 includes a comparator 516 and reference clock generator 522. Comparator 516 receives as a first input the output clock frequency associated with the output voltage signal generated by power converter 502. Comparator 516 also receives as a second input a reference clock signal generated by the reference clock generator 522.

The clock generation circuit is coupled to an FCFD circuit 534 and an FM circuit 528. The FM circuit 528 comprises suitable circuitry, logic, interfaces, and/or code and is configured to generate an average clock signal based on the input clock signal 511 measured during a first pre-configured interval. The FCFD circuit 534 comprises suitable circuitry, logic, interfaces, and/or code and is configured to detect a clock frequency above a threshold during a second pre-configured interval. In some aspects, the first pre-configured interval is larger than the second pre-configured interval.

The frequency comparator 540 comprises suitable circuitry, logic, interfaces, and/or code and is configured to generate a clock comparison signal based on the detected clock frequency generated by the FCFD circuit 534 and the average clock signal generated by the FM circuit 528. The clock comparison signal generated by the frequency comparator 540 is communicated as input to the reference clock generator 522 and is used for generating the reference clock signal communicated as input to comparator 516.

The power converter 504 generates output voltage using an input clock signal 513 generated by the clock generation circuit 512. The clock generation circuit 512 includes a comparator 518 and reference clock generator 524. Comparator 518 receives as a first input the output clock frequency associated with the output voltage signal generated by power converter 504. Comparator 518 also receives as a second input a reference clock signal generated by the reference clock generator 524.

The clock generation circuit is coupled to an FCFD circuit 536 and an FM circuit 530. The FM circuit 530 comprises suitable circuitry, logic, interfaces, and/or code and is configured to generate an average clock signal based on the input clock signal 513 measured during a first pre-configured interval. The FCFD circuit 536 comprises suitable circuitry, logic, interfaces, and/or code and is configured to detect a clock frequency above a threshold during a second pre-configured interval. In some aspects, the first pre-configured interval is larger than the second pre-configured interval.

The frequency comparator 542 comprises suitable circuitry, logic, interfaces, and/or code and is configured to generate a clock comparison signal based on the detected clock frequency generated by the FCFD circuit 536 and the average clock signal generated by the FM circuit 530. The clock comparison signal generated by the frequency comparator 542 is communicated as input to the reference clock generator 524 and is used for generating the reference clock signal communicated as input to comparator 518.

The power converter 506 generates output voltage using an input clock signal 515 generated by the clock generation circuit 514. The clock generation circuit 514 includes a comparator 520 and reference clock generator 526. Comparator 520 receives as a first input the output clock frequency associated with the output voltage signal generated by power converter 506. Comparator 520 also receives as a second input a reference clock signal generated by the reference clock generator 526.

The clock generation circuit 514 is coupled to an FCFD circuit 538 and an FM circuit 532. The FM circuit 532 comprises suitable circuitry, logic, interfaces, and/or code and is configured to generate an average clock signal based on the input clock signal 515 measured during a first pre-configured interval. The FCFD circuit 538 comprises suitable circuitry, logic, interfaces, and/or code and is configured to detect a clock frequency above a threshold during a second pre-configured interval. In some aspects, the first pre-configured interval is larger than the second pre-configured interval.

The frequency comparator 544 comprises suitable circuitry, logic, interfaces, and/or code and is configured to generate a clock comparison signal based on the detected clock frequency generated by the FCFD circuit 538 and the average clock signal generated by the FM circuit 532. The clock comparison signal generated by the frequency comparator 544 is communicated as input to the reference clock generator 526 and is used for generating the reference clock signal communicated as input to comparator 520.

In some embodiments, daisy-chain connections 552A, 552B, . . . 552N are configured between FM circuits 528, 530, . . . , 532. Additionally, a shared communication bus 554 can be configured between the FCFD circuits 534, 536, . . . , 538. The shared communication bus 554 and/or the daisy-chain connections 552A, 552B, . . . , 552N can be used for communicating average clock signals or clock comparison signals generated by the corresponding FM circuits or frequency comparators. The average clock signals or clock comparison signals communicated via the shared communication bus 554 and/or the daisy-chain connections 552A, 552B, . . . , 552N can be used by a frequency comparator to further adjust its clock comparison signal that is communicated to the corresponding reference clock generator.

In some aspects, the shared communication bus 554 and/or the daisy-chain connections 552A, 552B, . . . , 552N are used for communicating each switched capacitor power converter's fast comparator output clock (e.g., the output of each FCFD circuit) to every other converter for steady-state frequency adjustment.

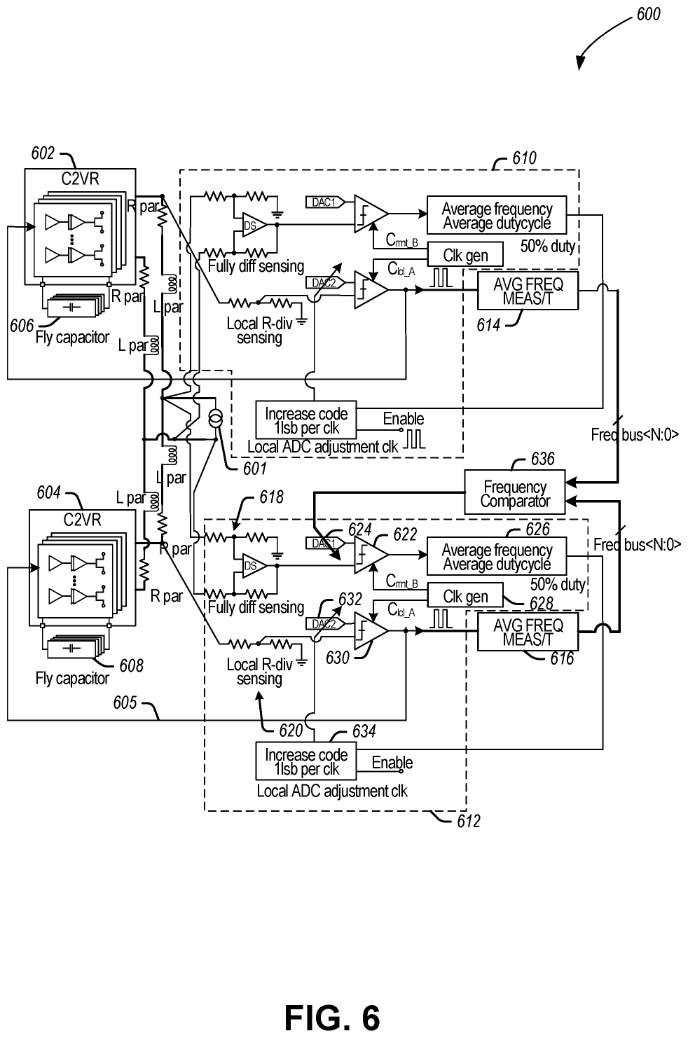

FIG. 6 is a diagram of the cross-regulation system implementation of FIG. 5 on a circuit-level testbench, in accordance with some embodiments. Referring to FIG. 6, the cross-regulation system 600 includes power converters 602 and 604 supplying power to load 601 using corresponding capacitor banks 606 and 608.

The power converter 602 is configured to generate an output voltage signal using an input clock signal generated by the clock generation circuit 610 coupled to an FM circuit 614. Similarly, the power converter 604 is configured to generate an output voltage signal using an input clock signal generated by the clock generation circuit 612 coupled to an FM circuit 616 and a frequency comparator 636. In some aspects, frequency comparator 636 receives clock signal input from different FM circuits associated with different power converters, such as FM circuit 614 and FM circuit 616.

In some aspects, clock generation circuit 612 includes a differential sensing circuit 618, a local sensing circuit 620, a first comparator 622, a second comparator 630, a first digital-to-analog converter (DAC) 624, a second DAC 632, a clock generator 628, a frequency averaging circuit 626, and a DAC code adjustment circuit 634. As illustrated in FIG. 6, the first comparator 622 generates an output clock signal based on the output clock frequency associated with the output voltage signal of the power converter 604 received by the differential sensing circuit 618. The first comparator 622 generates the output clock signal further based on a reference clock signal generated by the first DAC 624 based on input from the frequency comparator 636. The input clock signal 605 is generated at the output of the second comparator 630 based on input signals from the second DAC 632 (configured by the DAC code adjustment circuit 634) and the clock signal generated by the local sensing circuit 620.

In some aspects, clock generation circuit 610 includes the same circuits as clock generation circuit 612.

In some aspects, the C2VR local comparator output clock is measured and sent to other C2VR regulators. Other C2VR regulators can adjust the reference voltage to the remote comparator based on the pulse count difference in the steady state. In this regard, a slow-motion frequency adjustment is performed.

In some aspects, an under-voltage protection (UVP) signal travels between C2VR regulators and can be used for fast transient detection for each C2VR to balance the frequency during transient conditions. In some aspects, scalable to a large number of ganged power converters can be used, with daisy-chained slow/fast communication.

In some aspects, the frequency comparator 636 can be configured based on the following signal processing algorithm:
(1) Slow (remote loop) balance.
(a) Sharing the local DAC DV information (each is 1 bit, digital and slow). Dv_inc is a DV increase decision, and Dv_dec is a DV decrease decision.
(b) Each IP calculates local DV based on its local information and the neighbors' gang IP (to achieve balancing). In some aspects, increase/decrease DV is performed only after the same successive decisions (no matter from which IP), as opposed to 1 in non-ganged solutions).

In some aspects, a follower configuration can be used, where the IP is using only the information from the previous IP, ignoring its own. In some aspects, the DV window and DV step can vary (both are configurable) between different ganged IPs to achieve additional ganging fine-tuning (per use case simulations and/or silicon).
(2) Fast, transient balance.
Share existing under voltage protection (UVP) or under voltage warning (UVW), or any other signal associated with voltage droop/undershoot indication between the ganged IP. In some aspects, IP can trigger UVW based on its indication or another IP, such as IP (i−1) indication.

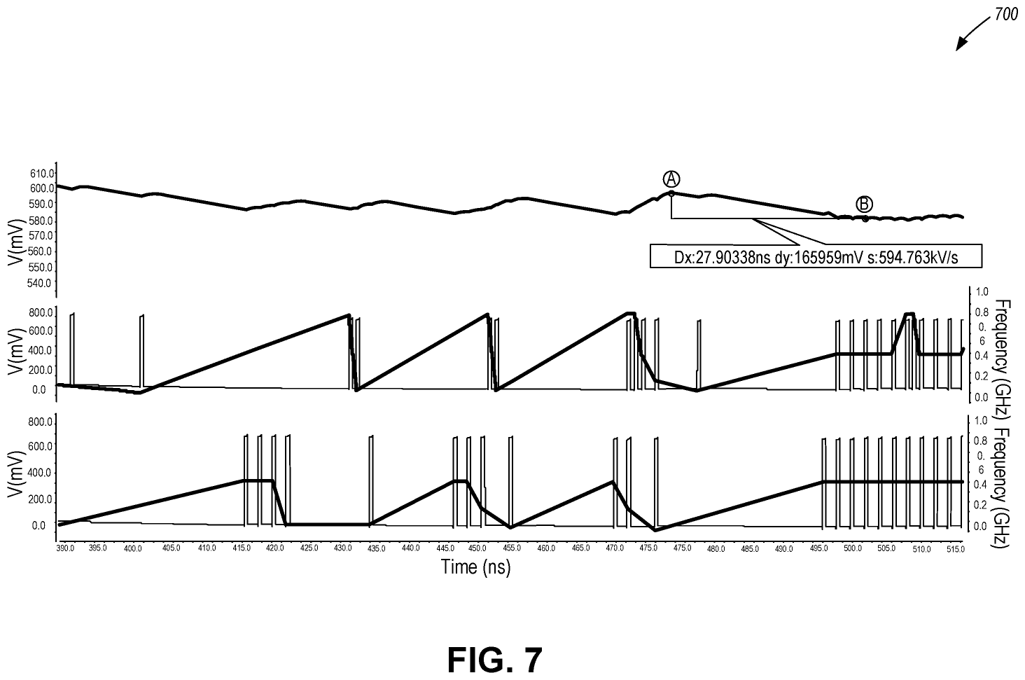

FIG. 7 illustrates graph 700 of simulation results for the cross-regulation system implementation of FIG. 5, in accordance with some embodiments.

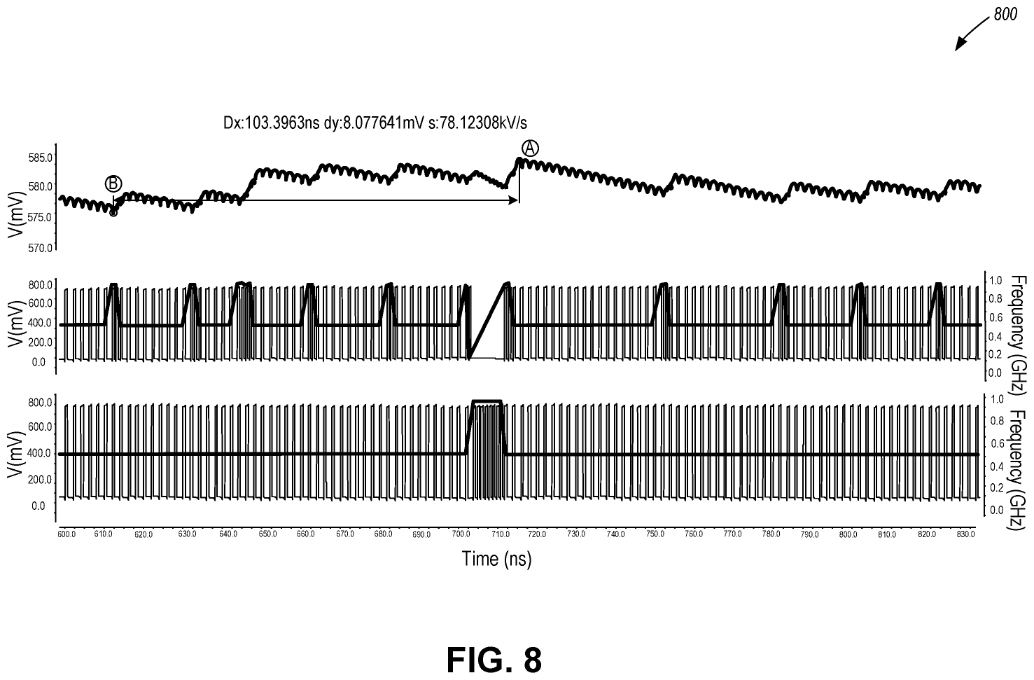

FIG. 8 illustrates graph 800 of simulation results for the cross-regulation system implementation of FIG. 5, in accordance with some embodiments.

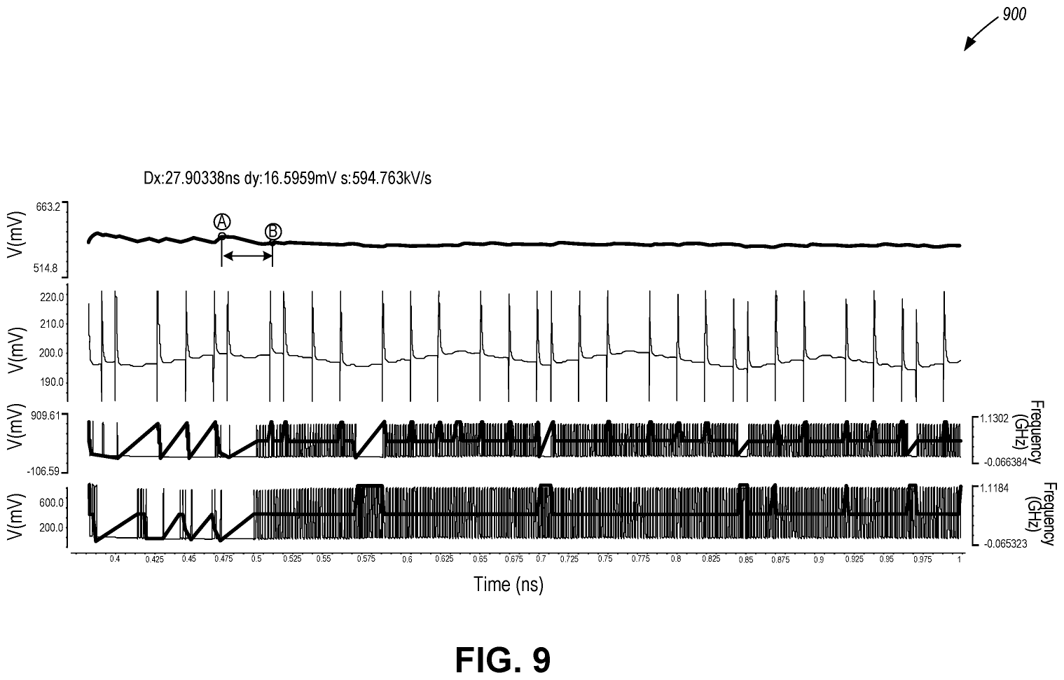

FIG. 9 illustrates graph 900 of simulation results for the cross-regulation system implementation of FIG. 5, in accordance with some embodiments.

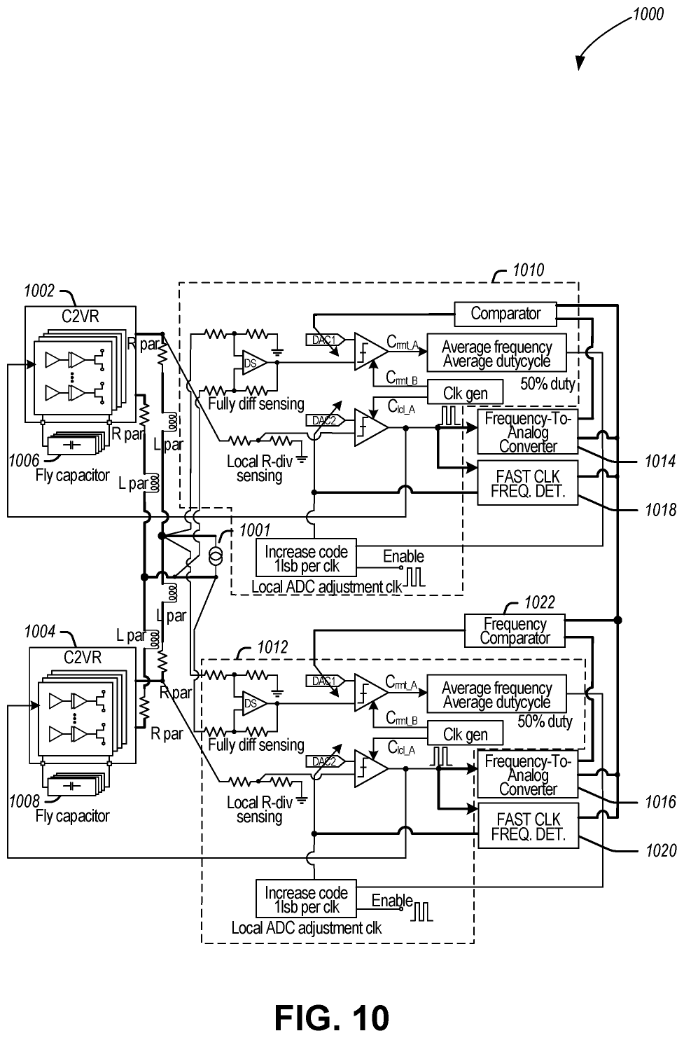

FIG. 10 is a diagram of a cross-regulation system 1000 using C2VRs on a circuit-level testbench, in accordance with some embodiments. Referring to FIG. 10, the cross-regulation system 1000 includes power converters 1002 and 1004 supplying power to load 1001 using corresponding capacitor banks 1006 and 1008.

The power converter 1002 is configured to generate an output voltage signal using an input clock signal generated by the clock generation circuit 1010 coupled to an FM circuit (e.g., frequency-to-analog converter 1014) and an FCFD circuit 1018. Similarly, the power converter 1004 is configured to generate an output voltage signal using an input clock signal generated by the clock generation circuit 1012 coupled to an FM circuit (e.g., frequency-to-analog converter 1016), an FCFD circuit 1020, and a frequency comparator 1022. In some aspects, frequency comparator 1022 receives clock signal input from different FM circuits (or frequency-to-analog converters) and FCFD circuits associated with different power converters, such as frequency-to-analog converters 1014 and 1016 and FCFD circuits 1018 and 1020.

In some aspects, the power converter local comparator output clock is translated into an analog solution using the frequency-to-analog converter 1014 or 1016. In some aspects, the analog signal is used to calculate an average frequency over all regulators. Each converter compares its frequency to an average value for steady state frequency/load balance. In some aspects, the FCFD circuits 1018 and 1020 are used for fast loop processing (e.g., to detect transient conditions). The instantaneous frequency is used to compare the running average frequency of the system and add weight to the reference voltage (the second DAC, or DAC2, in the preceding figures) to the local comparator for a quick frequency adjustment in transient conditions.

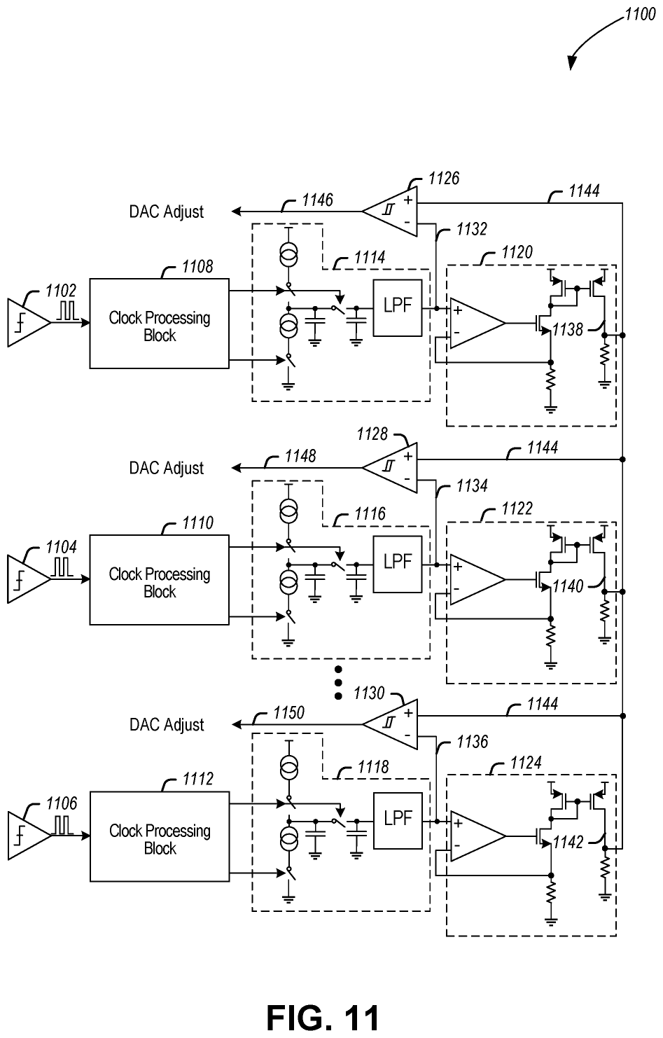

FIG. 11 is a diagram of an analog frequency-voltage converter followed by a voltage-to-current analog converter for averaging frequency over different converters, in accordance with some embodiments. Referring to FIG. 11, the cross-regulation system 1100 includes comparators 1102, 1104, . . . , 1106 generating input clock signals for corresponding clock processing blocks 1108, 1110, . . . , 1112 (which can be power converters).

Clock processing block 1108 is coupled to a pulse-to-direct current (DC) circuit 1114 (which can also be referred to as a frequency-voltage converter) and a voltage-to-current (V-to-I) analog converter 1120. The pulse-to-DC circuit 1114 generates a DC signal 1132. The V-to-I analog converter 1120 generates a local current signal 1138, which is averaged over similar current signals of the other clock processing blocks so that an average current signal 1144 is generated. The average current signal 1144 and the DC signal 1132 are communicated to comparator 1126, which generates a DAC adjust signal 1146. The DAC adjust signal 1146 can be used by at least one of the DACs in a clock generation circuit for purposes of adjusting the reference signal generated by the DAC.

Clock processing block 1110 is coupled to a pulse-to-DC circuit 1116 and a V-to-I analog converter 1122. The pulse-to-DC circuit 1116 generates a DC signal 1134. The V-to-I analog converter 1122 generates a local current signal 1140, which is averaged over similar current signals of the other clock processing blocks so that an average current signal 1144 is generated. The average current signal 1144 and the DC signal 1134 are communicated to comparator 1128, which generates a DAC adjust signal 1148. The DAC adjust signal 1148 can be used by at least one of the DACs in a clock generation circuit for purposes of adjusting the reference signal generated by the DAC.

Clock processing block 1112 is coupled to a pulse-to-DC circuit 1118 and a V-to-I analog converter 1124. The pulse-to-DC circuit 1118 generates a DC signal 1136. The V-to-I analog converter 1124 generates a local current signal 1142, which is averaged over similar current signals of the other clock processing blocks so that an average current signal 1144 is generated. The average current signal 1144 and the DC signal 1136 are communicated to comparator 1130, which generates a DAC adjust signal 1150. The DAC adjust signal 1150 can be used by at least one of the DACs in a clock generation circuit for purposes of adjusting the reference signal generated by the DAC.

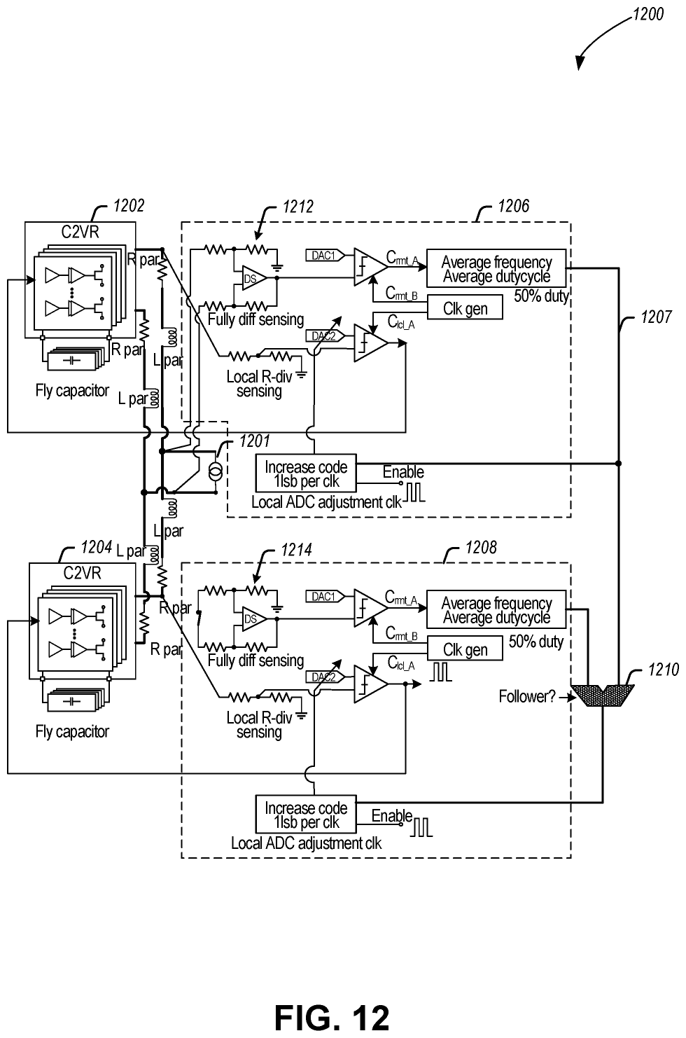

FIG. 12 is a diagram of a cross-regulation system using C2VRs, in accordance with some embodiments. Referring to FIG. 12, the cross-regulation system 1200 includes power converters 1202 and 1204 supplying power to load 1201 using corresponding capacitor banks.

The power converter 1202 is configured to generate an output voltage signal using an input clock signal generated by the clock generation circuit 1206 (which can be coupled to an FM circuit and an FCFD circuit). The clock generation circuit 1206 can include a differential sensing circuit 1212. Similarly, the power converter 1204 is configured to generate an output voltage signal using an input clock signal generated by the clock generation circuit 1208 (which can be coupled to an FM circuit and an FCFD circuit). The clock generation circuit 1208 can include a differential sensing circuit 1214.

In some aspects, power converter 1202 is configured as a primary power converter, and power converter 1204 is configured as a secondary power converter, obtaining configurations from the primary power converter. For example, the cross-regulation system 1200 further includes a multiplexer 1210. In some aspects, the differential sensing circuit 1214 is deactivated, and the clock generation circuit 1208 receives a clock reference signal 1207 from the clock generation circuit 1206 of the primary power converter (e.g., power converter 1202) via the multiplexer 1210.

In this regard, configuring one of the power converters in the cross-regulation system 1200 as a reference regulator (e.g., a primary power converter), the remote comparator of the reference regulator will regulate all the DAC across other C2VR local comparators.

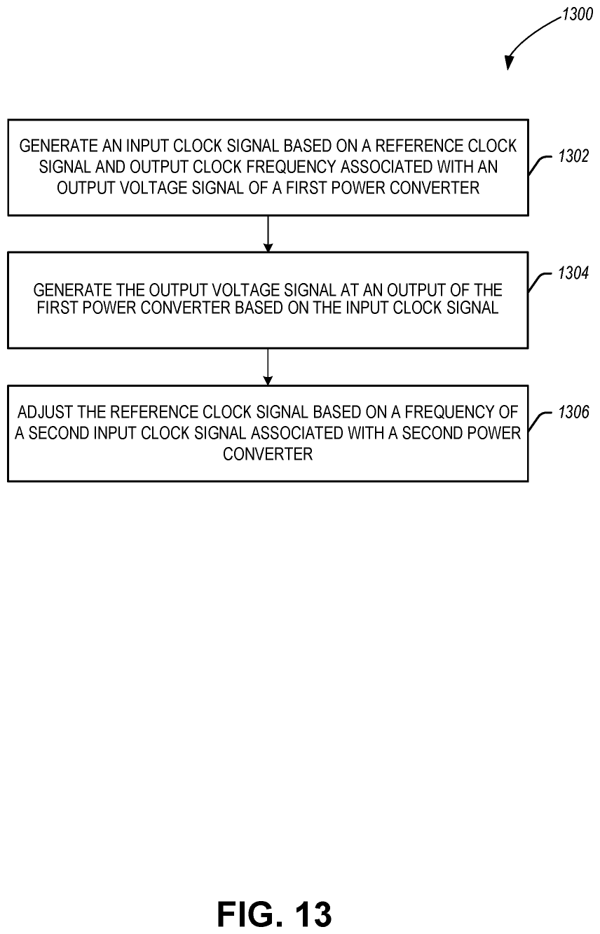

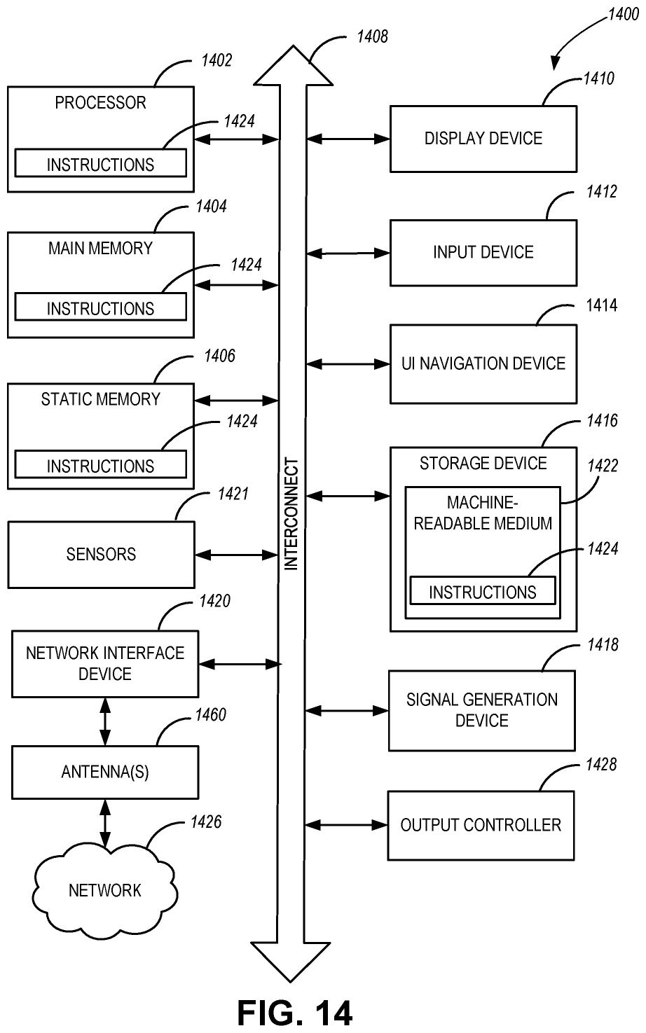

FIG. 13 is a flow diagram of an example method 1300 for generating an input clock signal for a power converter, in accordance with some embodiments. Referring to FIG. 13, method 1300 includes operations 1302, 1304, and 1306, which may be executed by a processor in a cross-regulation system or another processor of a computing device (e.g., hardware processor 1402 of machine 1400 illustrated in FIG. 14, which can include one or more of the circuits illustrated in FIGS. 1-12). In some embodiments, one or more of the circuits illustrated in FIGS. 1-12 can perform the functionalities discussed in FIG. 13 as well as in the examples listed below.

At operation 1302, an input clock signal (e.g., input clock signal 511) is generated based on a reference clock signal (e.g., the signal output of reference clock generator 522) and output clock frequency associated with an output voltage signal of a first power converter (e.g., the output voltage signal of the power converter 502).

At operation 1304, the output voltage signal is generated at an output of the first power converter based on the input clock signal (e.g., based on the input clock signal 511).

At operation 1306, the reference clock signal is adjusted based on a frequency of a second input clock signal associated with a second power converter. For example, the signal output of reference clock generator 522 is adjusted based on the output of the frequency comparator 540, which in turn is based on, e.g., the second input clock signal (e.g., input clock signal 513) associated with a second power converter (e.g., power converter 504).

FIG. 14 illustrates a block diagram of an example machine 1400 upon which any one or more of the techniques (e.g., methodologies) discussed herein may perform. In alternative embodiments, the machine 1400 may operate as a standalone device or may be connected (e.g., networked) to other machines. In a networked deployment, machine 1400 may operate in the capacity of a server machine, a client machine, or both in server-client network environments. In an example, machine 1400 may function as a peer machine in a peer-to-peer (P2P) (or other distributed) network environment. The machine 1400 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1400 may include a hardware processor 1402 (e.g., a central processing unit (CPU), a graphics processing unit (GPU), a hardware processor core, or any combination thereof), a main memory 1404, and a static memory 1406, some or all of which may communicate with each other via an interlink 1408 (e.g., a bus). In some aspects, the main memory 1404, the static memory 1406, or any other type of memory (including cache memory) used by machine 1400 can be configured based on the disclosed techniques or can implement the disclosed memory devices.

Specific examples of main memory 1404 include Random Access Memory (RAM) and semiconductor memory devices, which may include, in some embodiments, storage locations in semiconductors such as registers. Specific examples of static memory 1406 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1400 may further include a display device 1410, an input device 1412 (e.g., a keyboard), and a user interface (UI) navigation device 1414 (e.g., a mouse). In an example, the display device 1410, input device 1412, and UI navigation device 1414 may be a touch screen display. The machine 1400 may additionally include a storage device (e.g., drive unit or another mass storage device) 1416, a signal generation device 1418 (e.g., a speaker), a network interface device 1420, and one or more sensors 1421, such as a global positioning system (GPS) sensor, compass, accelerometer, or other sensors. The machine 1400 may include an output controller 1428, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1402 and/or instructions 1424 may comprise processing circuitry and/or transceiver circuitry.

The storage device 1416 may include a machine-readable medium 1422 on which one or more sets of data structures or instructions 1424 (e.g., software) embodying or utilized by any one or more of the techniques or functions described herein can be stored. Instructions 1424 may also reside, completely or at least partially, within the main memory 1404, within static memory 1406, or the hardware processor 1402 during execution thereof by the machine 1400. In an example, one or any combination of the hardware processor 1402, the main memory 1404, the static memory 1406, or the storage device 1416 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1422 is illustrated as a single medium, the term “machine-readable medium” may include a single medium or multiple media (e.g., a centralized or distributed database and/or associated caches and servers) configured to store instructions 1424.

An apparatus of the machine 1400 may be one or more of a hardware processor 1402 (e.g., a central processing unit (CPU), a graphics processing unit (GPU), a hardware processor core, or any combination thereof), a main memory 1404 and a static memory 1406, one or more sensors 1421, a network interface device 1420, one or more antennas 1460, a display device 1410, an input device 1412, a UI navigation device 1414, a storage device 1416, instructions 1424, a signal generation device 1418, and an output controller 1428. The apparatus may be configured to perform one or more of the methods and/or operations disclosed herein. The apparatus may be intended as a component of machine 1400 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1400 and that causes machine 1400 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1424 may further be transmitted or received over a communications network 1426 using a transmission medium via the network interface device 1420 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, 3GPP family of standards (including 5G and beyond standards), a Universal Mobile Telecommunications System (UMTS) family of standards, peer-to-peer (P2P) networks, among others.

In an example, the network interface device 1420 may include one or more physical jacks (e.g., Ethernet, coaxial, or phone jacks) or one or more antennas to connect to the communications network 1426. In an example, the network interface device 1420 may include one or more antennas 1460 to wirelessly communicate using at least one single-input multiple-output (SIMO), multiple-input multiple-output (MIMO), or multiple-input single-output (MISO) techniques. In some examples, the network interface device 1420 may wirelessly communicate using multiple-user MIMO techniques. The term “transmission medium” shall be taken to include any intangible medium that can store, encode, or carry instructions for execution by the machine 1400 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented wholly or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended; that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar. However, the scope of the disclosure is not limited in this respect.

Described implementations of the subject matter can include one or more features, alone or in combination, as illustrated below by way of examples.

Example 1 is an apparatus comprising a power converter comprising an input terminal and an output terminal; a first comparator, wherein a first input of the first comparator is coupled to the output terminal of the power converter; and a reference clock generator, wherein an output of the reference clock generator is coupled to a second input of the first comparator, and an input of the reference clock generator is coupled to a frequency comparator.

In Example 2, the subject matter of Example 1 includes subject matter where the reference clock generator comprises a first digital-to-analog converter (DAC), wherein an input of the first DAC is coupled to an output of the frequency comparator.

In Example 3, the subject matter of Example 2 includes subject matter where the frequency comparator comprises a first input coupled to a first frequency measurement circuit of the power converter and a second input coupled to a second frequency measurement circuit of a second power converter.

In Example 4, the subject matter of Example 3 includes a second comparator comprising a first input terminal and a second input terminal, wherein the first input terminal of the second comparator is coupled to a second DAC.

In Example 5, the subject matter of Example 4 includes subject matter where the second input terminal of the second comparator is coupled to the output terminal of the power converter.

In Example 6, the subject matter of Examples 4-5 includes subject matter where an output terminal of the second comparator is coupled to an input terminal of the first frequency measurement circuit.

In Example 7, the subject matter of Example 6 includes subject matter where the output terminal of the second comparator is coupled to the input terminal of the power converter.

In Example 8, the subject matter of Examples 4-7 includes subject matter where the frequency comparator is coupled to an output terminal of a fast clock frequency detection circuit.

In Example 9, the subject matter of Example 8 includes subject matter where the second input terminal of the second comparator is coupled to an input terminal of the fast clock frequency detection circuit.

In Example 10, the subject matter of Examples 1-9 includes a differential sensing circuit comprising an input terminal and an output terminal, the input terminal of the differential sensing circuit coupled to the output terminal of the power converter, and the output terminal of the differential sensing circuit coupled to the first input of the first comparator.

Example 11 is an apparatus comprising a clock generation circuit comprising a first comparator, the first comparator to generate an input clock signal based on a reference clock signal and an output clock frequency associated with an output voltage signal; a first power converter coupled to the clock generation circuit, the first power converter to generate the output voltage signal based on the input clock signal; and a reference clock generator coupled to the first comparator, the reference clock generator to adjust the reference clock signal based on at least a frequency of a second input clock signal associated with a second power converter.

In Example 12, the subject matter of Example 11 includes a frequency comparator to generate a frequency output signal based on a frequency of the input clock signal and the frequency of the second input clock signal.

In Example 13, the subject matter of Example 12 includes subject matter where the reference clock generator comprises a first digital-to-analog converter (DAC), the first DAC to generate the reference clock signal as an analog signal output based on the frequency output signal.

In Example 14, the subject matter of Examples 12-13 includes subject matter where the frequency comparator is coupled to a first frequency measurement circuit of the power converter and a second frequency measurement circuit of the second power converter.

In Example 15, the subject matter of Examples 13-14 includes subject matter where the clock generation circuit further comprises a differential sensing circuit coupled to the first power converter, the differential sensing circuit generates a sensed voltage signal based on the output voltage signal.

In Example 16, the subject matter of Example 15 includes subject matter where the first comparator is to generate an output clock signal based on the sensed voltage signal and the analog signal output.

In Example 17, the subject matter of Example 16 includes subject matter where the clock generation circuit further comprises a second comparator, the second comparator comprises a first input coupled to a second DAC, and the second comparator generates the input clock signal based on the output clock signal.

In Example 18, the subject matter of Example 17 includes subject matter where the second comparator comprises a second input receiving the output clock frequency associated with the output voltage signal.

In Example 19, the subject matter of Examples 11-18 includes a pulse-to-direct current (DC) converter coupled to an output of the first power converter, the pulse-to-DC converter, to generate a DC signal based on the output voltage signal.

In Example 20, the subject matter of Example 19 includes a voltage-to-current (V-to-I) amplifier coupled to the pulse-to-DC converter, the V-to-I amplifier to generate a current signal based on the DC signal, the current signal corresponding to the output voltage signal.

In Example 21, the subject matter of Example 20 includes a second comparator coupled to the pulse-to-DC converter and the V-to-I amplifier, the second comparator to generate a digital-to-analog converter (DAC) signal based on the DC signal and an average current signal, the average current signal based on the current signal and at least a second current signal associated with the second power converter.

In Example 22, the subject matter of Example 21 includes subject matter where the reference clock generator is to adjust the reference clock signal based on the DAC signal.

Example 23 is a system comprising memory and at least one processor coupled to the memory, the at least one processor generates an input clock signal based on a reference clock signal and output clock frequency associated with an output voltage signal of a first power converter; generate the output voltage signal at an output of the first power converter based on the input clock signal; and adjust the reference clock signal based on a frequency of a second input clock signal associated with a second power converter.

In Example 24, the subject matter of Example 23 includes subject matter where the at least one processor is to generate a frequency output signal based on a frequency of the input clock signal and the frequency of the second input clock signal.

In Example 25, the subject matter of Example 24 includes subject matter where the at least one processor is to generate the reference clock signal as an analog signal output from a digital-to-analog converter (DAC) based on the frequency output signal.

In Example 26, the subject matter of Example 25 includes subject matter where the at least one processor is to generate a sensed voltage signal based on the output voltage signal.

In Example 27, the subject matter of Example 26 includes subject matter where the at least one processor is to generate an output clock signal based on the sensed voltage signal and the analog signal output.

In Example 28, the subject matter of Example 27 includes subject matter where the at least one processor is to generate the input clock signal based on the output clock signal.

In Example 29, the subject matter of Examples 23-28 includes subject matter where the at least one processor is to generate a DC signal based on the output voltage signal.

In Example 30, the subject matter of Example 29 includes subject matter where the at least one processor is to generate a current signal corresponding to the output voltage signal based on the DC signal.

In Example 31, the subject matter of Example 30 includes subject matter where the at least one processor is to generate a digital-to-analog converter (DAC) signal based on the DC signal and an average current signal, the average current signal based on the current signal and at least a second current signal associated with the second power converter.

In Example 32, the subject matter of Example 31 includes subject matter where the at least one processor is to adjust the reference clock signal based on the DAC signal.

Example 33 is a method comprising generating an input clock signal based on a reference clock signal and output clock frequency associated with an output voltage signal of a first power converter; generating the output voltage signal at an output of the first power converter based on the input clock signal; and adjusting the reference clock signal based on a frequency of a second input clock signal associated with a second power converter.

In Example 34, the subject matter of Example 33 includes generating a frequency output signal based on a frequency of the input clock signal and the frequency of the second input clock signal.

In Example 35, the subject matter of Example 34 includes generating the reference clock signal as an analog signal output from a digital-to-analog converter (DAC) based on the frequency output signal.

In Example 36, the subject matter of Example 35 includes generating a sensed voltage signal based on the output voltage signal.

In Example 37, the subject matter of Example 36 includes generating an output clock signal based on the sensed voltage signal and the analog signal output.

In Example 38, the subject matter of Example 37 includes generating the input clock signal based on the output clock signal.

In Example 39, the subject matter of Examples 33-38 includes generating a DC signal based on the output voltage signal.

In Example 40, the subject matter of Example 39 includes generating a current signal corresponding to the output voltage signal based on the DC signal.

In Example 41, the subject matter of Example 40 includes generating a digital-to-analog converter (DAC) signal based on the DC signal and an average current signal, the average current signal based on the current signal and at least a second current signal associated with the second power converter.

In Example 42, the subject matter of Example 41 includes adjusting the reference clock signal based on the DAC signal.

Example 43 is an apparatus comprising means to perform a method as Exampled in any preceding claim.

Example 44 is machine-readable storage including machine-readable instructions, which, when executed, causes a transceiver to implement a method as shown in any preceding claim.

Example 45 is machine-readable storage including machine-readable instructions, which, when executed, causes an equalization circuit to implement a method as shown in any preceding claim.

Example 46 is a computer program comprising instructions which, when a computer executes the program, causes the computer to carry out the method as Exampled in any preceding claim.

Example 47 is at least one machine-readable medium including instructions that, when executed by processing circuitry, cause the processing circuitry to perform operations to implement any of Examples 1-46.

Example 48 is an apparatus comprising means to implement any of Examples 1-46.

Example 49 is a system to implement any of Examples 1-46.

Example 50 is a method to implement any of Examples 1-46.

The above description is intended to be illustrative and not restrictive. For example, the above-described examples (or one or more aspects thereof) may be used in combination with others. Other embodiments may be used, such as by one of ordinary skill in the art upon reviewing the above description. The Abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are now incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising
a power converter comprising an input terminal and an output terminal;
a first comparator, wherein a first input of the first comparator is coupled to the output terminal of the power converter; and
a reference clock generator, wherein an output of the reference clock generator is coupled to a second input of the first comparator, and an input of the reference clock generator is coupled to a frequency comparator.

2. The apparatus of claim 1, wherein the reference clock generator comprises a first digital-to-analog converter (DAC), wherein an input of the first DAC is coupled to an output of the frequency comparator.

3. The apparatus of claim 2, wherein the frequency comparator comprises a first input coupled to a first frequency measurement circuit of the power converter and a second input coupled to a second frequency measurement circuit of a second power converter.

4. The apparatus of claim 3, further comprising:
a second comparator comprising a first input terminal and a second input terminal, wherein the first input terminal of the second comparator is coupled to a second DAC.

5. The apparatus of claim 4, wherein the second input terminal of the second comparator is coupled to the output terminal of the power converter.

6. The apparatus of claim 4, wherein an output terminal of the second comparator is coupled to an input terminal of the first frequency measurement circuit.

7. The apparatus of claim 6, wherein the output terminal of the second comparator is coupled to the input terminal of the power converter.

8. The apparatus of claim 4, wherein the frequency comparator is coupled to an output terminal of a clock frequency detection circuit.

9. The apparatus of claim 8, wherein the clock frequency detection circuit is a fast clock frequency detection circuit, and wherein the second input terminal of the second comparator is coupled to an input terminal of the fast clock frequency detection circuit.

10. The apparatus of claim 1, further comprising:
a differential sensing circuit comprising an input terminal and an output terminal, the input terminal of the differential sensing circuit coupled to the output terminal of the power converter, and the output terminal of the differential sensing circuit coupled to the first input of the first comparator.

11. The apparatus of claim 1, wherein the apparatus comprises a processor, and wherein the processor includes at least two of: the power converter, the first comparator, and the reference clock generator.

12. The apparatus of claim 1, wherein the apparatus comprises a processor, wherein the processor includes the power converter, the first comparator, and the reference clock generator, and wherein the processor comprises one or more interconnects between the power converter, the first comparator, and the reference clock generator.

13. The apparatus of claim 1, wherein the apparatus comprises one or more interfaces between the power converter and the reference clock generator.

14. An apparatus comprising:
a clock generation circuit comprising a first comparator, the first comparator to generate an input clock signal based on a reference clock signal and an output clock frequency associated with an output voltage signal;
a first power converter coupled to the clock generation circuit, the first power converter to generate the output voltage signal based on the input clock signal; and
a reference clock generator coupled to the first comparator, the reference clock generator to adjust the reference clock signal based on at least a frequency of a second input clock signal associated with a second power converter.

15. The apparatus of claim 14, further comprising:
a frequency comparator to generate a frequency output signal based on a frequency of the input clock signal and the frequency of the second input clock signal.

16. The apparatus of claim 15, wherein the reference clock generator comprises a first digital-to-analog converter (DAC), the first DAC to generate the reference clock signal as an analog signal output based on the frequency output signal.

17. The apparatus of claim 15, wherein the frequency comparator is coupled to a first frequency measurement circuit of the power converter and a second frequency measurement circuit of the second power converter.

18. The apparatus of claim 16, wherein the clock generation circuit further comprises:
differential sensing circuit coupled to the first power converter, the differential sensing circuit to generate a sensed voltage signal based on the output voltage signal.

19. A method comprising:
generating an input clock signal based on a reference clock signal and output clock frequency associated with an output voltage signal of a first power converter;
generating the output voltage signal at an output of the first power converter based on the input clock signal; and
adjusting the reference clock signal based on a frequency of a second input clock signal associated with a second power converter.

20. The method of claim 19, further comprising:
generating a frequency output signal based on a frequency of the input clock signal and the frequency of the second input clock signal;
generating the reference clock signal as an analog signal output from a digital-to-analog converter (DAC) based on the frequency output signal;
generating a sensed voltage signal based on the output voltage signal; and
generating an output clock signal based on the sensed voltage signal and the analog signal output.
